(19) United States
(12) Patent Application Publication
(10) Pub. No.: US 2023/0391805 A1
(43) Pub. Date: Dec. 7, 2023

(54) GERMANIUM PRECURSORS, METHODS OF FORMING THE GERMANIUM PRECURSORS, AND PRECURSOR COMPOSITIONS COMPRISING THE GERMANIUM PRECURSORS

(71) Applicant: Micron Technology, Inc., Boise, ID (US)

(72) Inventors: Gurtej S. Sandhu, Boise, ID (US); Sumeet C. Pandey, Boise, ID (US); Stefan Uhlenbrock, Boise, ID (US); John A. Smythe, Boise, ID (US)

(21) Appl. No.: 18/327,840

(22) Filed: Jun. 1, 2023

Related U.S. Application Data
(60) Provisional application No. 63/365,774, filed on Jun. 2, 2022.

(51) Int. Cl. C07F 7/30; C23C 16/455; C23C 16/18

(52) U.S. Cl. CPC C07F 7/30; C23C 16/45553; C23C 16/18; H01L 21/02532

(57) ABSTRACT

A germanium precursor comprising a chemical formula of Ge(R¹NC(R³)NR²)(R⁴) where each of R¹, R², R³, and R⁴ is independently selected from the group consisting of hydrogen, an alkyl, a substituted alkyl, an alkoxide, a substituted amide, an amine, a substituted amine, and a halogen. Methods of forming the germanium precursor and a precursor composition including the germanium precursor are also disclosed.

### CROSS-REFERENCE TO RELATED APPLICATION

This application claims the benefit under 35 U.S.C. § 119(e) of U.S. Provisional Patent Application Ser. No. 63/365,774, filed Jun. 2, 2022, the disclosure of which is hereby incorporated herein in its entirety by this reference.

### TECHNICAL FIELD

Embodiments disclosed herein relate to electronic device fabrication including precursor compounds for forming a germanium-containing material. More specifically, germanium precursor compounds, methods of forming the germanium precursor compounds, and precursor compositions comprising the germanium precursors are disclosed.

### BACKGROUND

Germanium (Ge) is a widely used semiconductive material in the manufacture of electronic devices. Aside from the underlying intrinsic semiconducting properties observed in Ge, Ge is incorporated into silicon (Si)Ge (SiGe), and Ge-antimony(Sb)-tellurium(Te) (GST) chalcogenides.

Processes for forming Ge include physical vapor deposition (PVD) and chemical vapor deposition (CVD), such as high temperature thermal CVD processes or plasma-enhanced CVD (PECVD) processes. Ge is conventionally prepared using germane (GeH₄) or Ge butylamidinate (GeBAMDN) precursors. GeH₄ is conventionally used to form germanium films but utilizes deposition temperatures above 500° C., which temperatures are not compatible with temperature sensitive materials used in the electronic devices. Techniques for forming Ge also include atomic layer deposition (ALD), using a Ge precursor such as GeBAMDN and a reducing agent such as ammonia.

### BRIEF DESCRIPTION OF THE DRAWINGS

FIG. 1 is a simplified cross-sectional view of an electronic device including a germanium-containing material formed in accordance with embodiments of the disclosure.

FIG. 2 is a simplified cross sectional view of an additional electronic device including a germanium-containing material in accordance with embodiments of the disclosure.

FIG. 3 is a schematic block diagram illustrating an electronic device including a germanium-containing material in accordance with embodiments of the disclosure.

FIG. 4 is a schematic block diagram illustrating a system including a germanium-containing material in accordance with embodiments of the disclosure.

### DETAILED DESCRIPTION

Subvalent germanium (Ge) precursors are disclosed, as are methods of forming the subvalent Ge precursors, and precursor compositions including the subvalent Ge precursors. The Ge-containing material may be formed by an atomic layer deposition (ALD) process or by an atomic layer epitaxy (ALE) process at a low temperature and without using a plasma. The subvalent Ge precursor according to embodiments of the disclosure may be sufficiently reactive to form the Ge-containing material while exhibiting stability (e.g., thermal stability) under conditions of the ALD process or ALE process. The subvalent Ge precursors may, therefore, be used instead of conventional Ge(IV) precursors for ALD or ALE processes. Electronic devices that include the Ge-containing material and one or more temperature sensitive materials may, therefore, be fabricated by a lower temperature process.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “alkyl” means and includes a saturated, unsaturated, straight, branched, or cyclic hydrocarbon chain including from one carbon atom (C₁) to ten carbon atoms (C₁₀), such as from one carbon atom (C₁) to six carbon atoms (C₆).

As used herein, the term “amide” means and includes a —NR′R″ where R′ and R″ are independently an alkyl, a substituted alkyl, an alkoxide, a substituted alkoxide, an amide, a substituted amide, an amine, a substituted amine, or a halogen.

As used herein, the term “amine” means and includes an —NH₂.

As used herein, the term “amidinate” means and includes an R¹—N—CR³═N—R², wherein the nitrogen atoms are bonded to a central carbon atom, and R¹, R² and R³ are independently an alkyl, a substituted alkyl, an alkoxide, a substituted alkoxide, an amide, a substituted amide, an amine, a substituted amine, an aryl, or a halogen. In the chemical formula above, the carbon atom is depicted as having a double bond to one of the nitrogen atoms and a single bond to another of the nitrogen atoms. However, the bond order may be shared between the N—C═N such that the π orbitals are delocalized. This delocalized bond may then form a metal-ligand (M-L) bond between a metal and the amidinate.

As used herein, the term “aryl” means and includes an aromatic ring compound, including, but not limited to, phenyl, indolyl, or thienyl.

As used herein, the term “aspect ratio” means and includes a ratio of a height of a feature to a width of a feature.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. The conductive material may be one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al), or an alloy thereof), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)).

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device or a 3D DRAM device.

As used herein, the term “germanium-containing material” means and includes a material including germanium atoms and, optionally, one or more atoms. The germanium-containing material comprises, consists of, or consists essentially of germanium.

As used herein, the term “halogen” means and includes fluoro, chloro, bromo, or iodo. The term “halogen” may also be referred to as its anionic form as “halide,” including, but not limited to, fluoride, chloride, bromide, or iodide.

As used herein, “insulative material” means and includes an electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN₃)), at least one dielectric oxynitride material (e.g., a silicon oxynitride (SiOₓN_{y})), and at least one dielectric carboxynitride material (e.g., a silicon carboxynitride (SiOₓC₂N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC₂N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “lability” means and includes how easily M-L bonds are broken. A compound in which M-L bonds are relatively easily broken are referred to as “labile.”

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “subvalent” means and includes an oxidation state for an atom that is less than its normal group oxidation state. By way of non-limiting example, since the normal group oxidation state of a germanium atom is four (Ge(IV)), subvalent germanium may include an oxidation state of one (Ge(I)), an oxidation state of two (Ge(II)), or an oxidation state of three (Ge(III)).

As used herein, the term “substituted” means and includes a functional group where one or more hydrogen atoms have been replaced by another functional group, such as an alkyl, alkoxide, amide, amine, aryl, or halogen.

As used herein, the term “substrate” means and includes a material (e.g., a base material) or construction upon which additional materials or components are formed. The substrate may be an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the substrate may include, but are not limited to, semiconductive materials, insulative materials, conductive materials, etc. One or more of the materials may be thermally sensitive. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped. When reference is made to a “substrate” or “base material” in the following description, previous process acts may have been conducted to form materials or structures in or on the substrate or base material.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the electronic device industry. In addition, the description provided herein does not form a complete description of an electronic device or a complete process flow for manufacturing electronic devices and the structures described below do not form a complete electronic device. Only those process acts and structures necessary to understand the embodiments described herein are described in detail below. Additional acts to form a complete electronic device including the structures described herein may be performed by conventional techniques.

Drawings presented herein are for illustrative purposes only, and are not meant to be actual views of any particular material, component, structure, electronic device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

The subvalent germanium precursor according to embodiments of the disclosure has a chemical structure of

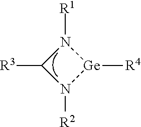

and a chemical formula of Ge(R¹NC(R³)NR²)(R⁴).

The amidinate is coordinated to the Ge atom. R¹ and R² are functional groups bonded to the nitrogen atoms of the amidinate, and R³ is a functional group on the central carbon atom of the amidinate. R⁴ is a functional group directly attached (e.g., bonded) to the Ge atom. By appropriately selecting the functional groups for R¹, R², R³ and R⁴, volatility, reactivity, lability, and stability of the subvalent Ge precursor may be tailored. Since the Ge atom is bonded (e.g., directly bonded) to the amidinate such that the bond is delocalized between two nitrogen atoms and bonded to R⁴, the Ge precursor is Ge(II) and is subvalent. Each of R¹, R², R³, R⁴ may independently be hydrogen, an alkyl, a substituted alkyl, an alkoxide, a substituted alkoxide, an amide, a substituted amide, an amine, a substituted amine, an amidinate, an aryl, a substituted aryl, or a halogen. The subvalent germanium precursor according to embodiments of the disclosure is stable yet exhibits a similar reactivity as a conventional ALD or ALE germanium precursor. Therefore, the subvalent germanium precursor is thermally stable and does not readily decompose at temperature or pressure conditions utilized in an ALD process or an ALE process conditions.

Each of R¹, R², R³ and R⁴ may be independently selected to provide the desired reactivity of the subvalent germanium precursor and to provide the desired stability of the subvalent germanium precursor. By way of example only, the functional groups may be selected to tailor steric hindrance and lability of the subvalent germanium precursor, which impacts the reactivity and stability of the subvalent germanium precursor. In addition to reactivity and stability, the functional groups for R¹, R², R³ and R⁴ may be selected to achieve a desired volatility of the subvalent germanium precursor. For instance, the functional groups for R¹, R², R³, and R⁴ may be appropriately selected to produce the subvalent germanium precursor in a solid phase or in a liquid phase suitable for use in the ALD process or the ALE process. The subvalent germanium precursor may, for example, be a solid or a liquid at room temperature (between about 20° C. and about 25° C.) but may be a gas at a temperature at which the ALD process or the ALE process is conducted. The solid or liquid subvalent germanium precursor may be vaporized by conventional techniques and using conventional equipment before use in the ALD process or the ALE process.

For example, R¹ and R² may, independently, be independently selected from a methyl, an ethyl, a propyl (e.g., an isopropyl), a butyl (e.g., a tert butyl), or a hexyl (e.g., a cyclohexyl). R¹ and R² may be the same functional group to provide a symmetric binding interaction between germanium and the amidinate. The symmetry may provide symmetric electron donating characteristics in the coordination to the germanium atom. In some embodiments, R¹ and R² are an isopropyl. In other embodiments, R¹ and R² are methyl, ethyl, n-butyl, tert-butyl, or cyclohexyl. However, R¹ and R² may be different functional groups depending on the desired volatility, reactivity, and stability of the subvalent germanium precursor.

R³ may be selected to provide steric and electronic behavior (e.g., electron bonding characteristics) to achieve specific precursor reactivity. For example, R¹ may be a methyl, an ethyl, a propyl (e.g., an n-propyl, an isopropyl), a butyl (e.g., an n-butyl, a tert-butyl,), or a phenyl. R³ may be the tert-butyl to enable high reactivity of the precursor coordinating to germanium. However, if a less reactive subvalent germanium precursor is desired, R³ may be an aryl, such as a phenyl, to enable lower reactivity of the precursor coordinating to germanium. In some embodiments, R³ is tert-butyl. In other embodiments, R³ is methyl, ethyl, n-propyl, isopropyl, n-butyl or phenyl.

R⁴ may also be selected to provide reactivity. For example, R⁴ may be a halide or an amidinate for a stable byproduct exchange. Specifically, coordination of the subvalent germanium to a hydrogenated surface of germanium would allow for an R⁴-H reduction and the subsequent binding of the germanium precursor to an exposed material. In some embodiments, R⁴ is a chloride.

The subvalent germanium precursor may include, but is not limited to, germanium chloro [2,2-dimethyl-N,N-bis(1-methylethyl)propanimidamidato)], germanium chloro [N,N-bis(1-methylethyl)pentanimidamidato)], or germanium chloro [N,N-bis(1-methylethyl)benzenimidamidato)], which have the following chemical structures:

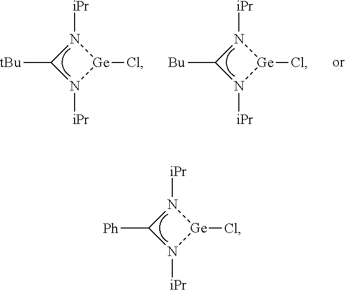

respectively.

Accordingly, a germanium precursor is disclosed and comprises a chemical structure of

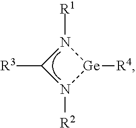

wherein each of R¹, R², R³ and R⁴ is independently selected from the group consisting of hydrogen, an alkyl, a substituted alkyl, an alkoxide, a substituted amide, an amine, a substituted amine, and a halogen.

The subvalent germanium precursor having the chemical formula Ge(R¹NC(R³)NR²)(R⁴) may be prepared (e.g., formed, synthesized) by reacting a lithium amidinate compound and a germanium source compound (e.g., a germanium compound). The lithium amidinate compound may be formed by reacting a lithium salt (e.g., a lithium alkyl compound or a lithium aryl compound) and a carbodiimide as shown in the reaction below:

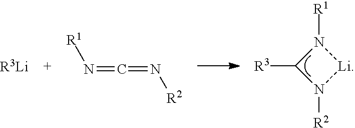

The lithium salt may have a chemical structure of R³Li, and the carbodiimide may have a chemical formula of R¹, R²-carbodiimide. The lithium salt is reacted with the carbodiimide to form a lithium amidinate compound with the chemical formula Li(R¹NC(R³)NR²). The carbodiimide may be appropriately selected depending on the desired R¹ and R² of the germanium precursor. The carbodiimide may include alkyl groups, aryl groups, etc. Similarly, the lithium salt may be selected depending on the desired R³ of the germanium precursor. The lithium salt and the carbodiimide may be commercially available or synthesized by conventional techniques. R¹, R², and R³ may be selected to provide steric, electronic, and reactivity behavior as discussed above for the germanium precursor. By way of example, R¹ and R¹ may be the same. In some embodiments, R¹ and R² are an isopropyl. In other embodiments, each of R¹ and R² are methyl, ethyl, n-butyl, tert-butyl, or cyclohexyl. However, R¹ and R² may be different functional groups depending on the desired volatility, reactivity, and stability of the subvalent germanium precursor. Additionally, R³ may be selected to provide steric and electronic behavior (e.g., electron bonding characteristics) to achieve specific precursor reactivity. For example, R³ may be a methyl, an ethyl, a propyl (e.g., an n-propyl, an isopropyl), a butyl (e.g., an n-butyl, a tert-butyl,), or a phenyl. For example, R³ may be the tert-butyl to enable high reactivity of the precursor coordinating to germanium. However, if a less reactive subvalent germanium precursor is desired, R³ may be an aryl, such as a phenyl, to enable lower reactivity of the precursor coordinating to germanium. In some embodiments, R³ is tert-butyl. In other embodiments, R³ is methyl, ethyl, n-propyl, isopropyl, n-butyl or phenyl.

The germanium precursor may be synthesized by a transmetalation reaction of a 1:1 or 2:1 stoichiometry of the lithium amidinate compound and the germanium source compound. By way of example, the germanium source compound may be R⁴₂Ge dioxane. The lithium amidinate compound and the germanium source compound may be reacted with a slight excess of LiR⁴ to transfer the amidinate ligand to the germanium yielding the subvalent germanium precursor (e.g., Ge(R¹ NC(R³)NR²)(R⁴)), as shown in the reaction scheme below:

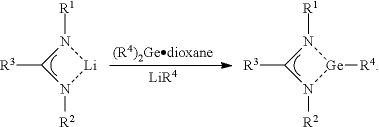

The lithium amidinate compound and the germanium source compound may be selected depending on the desired R⁴ of the subvalent germanium precursor, as described above. By way of example, R⁴ may be a halide. More specifically, the germanium source compound may be germanium dichloride, germanium dibromide, or germanium diiodide, and may be used with the complementary halide lithium salt. In some embodiments, R⁴ is chloride, and germanium dichloride may be used with the complementary LiCl salt to form the germanium precursor.

To form the germanium-containing material, the subvalent germanium precursor may be introduced to a chamber (e.g., an ALD deposition chamber, an ALE deposition chamber). The subvalent germanium precursor is formulated into a precursor composition and subsequently volatilized for use in an ALD process or in an ALE process. The precursor composition may include the subvalent germanium precursor and a solvent if the subvalent germanium precursor is to be introduced in a liquid delivery process. The subvalent germanium precursor may be introduced into the chamber as a solution or as a suspension depending on the liquid delivery process to be used. The solvent may be a conventional solvent used in precursor compositions, such as an aqueous solvent or an organic solvent. If the subvalent germanium precursor is a solid at room temperature, the subvalent germanium precursor is vaporized before being introduced into the chamber.

Accordingly, a method of forming a germanium precursor is disclosed, and

comprises reacting an organolithium reagent with a carbodiimide to produce a lithium amidinate compound. The lithium amidinate compound comprises a chemical structure of

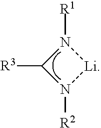

Each of R¹, R², and R³ is independently selected from the group consisting of hydrogen, an alkyl, a substituted alkyl, an alkoxide, a substituted amide, an amine, a substituted amine, and a halogen. The method further comprises reacting the lithium amidinate compound with a germanium source compound to form a germanium amidinate precursor comprising a chemical structure of

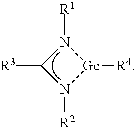

R⁴ is selected from the group consisting of hydrogen, an alkyl, a substituted alkyl, an alkoxide, a substituted amine, and a halogen.

Accordingly, a precursor composition is disclosed and comprises a germanium precursor and a solvent. The germanium precursor comprises a chemical structure of

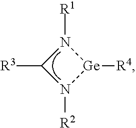

where each of R¹, R², R³ and R⁴ is independently selected from the group consisting of hydrogen, an alkyl, a substituted alkyl, an alkoxide, a substituted amide, an amine, a substituted amine, and a halogen.

The subvalent germanium precursor may be used to form the germanium-containing material, which may include, but is not limited to, elemental germanium, silicon germanium (SiGe), germanium doped with phosphorus, or a chalcogenide material including germanium. The Ge-containing material is formed at a low temperature without using a plasma. By way of example only, the Ge-containing material may be formed at a temperature of from about 20° C. to about 300° C., such as from about 20° C. to about 200° C. or from about 20° C. to about 150° C. Since the Ge-containing material is formed at a low temperature, the methods of forming the Ge-containing material are compatible with thermally sensitive materials of an electronic device that may be exposed during the ALD process or ALE process. The Ge-containing material formed by the methods of the disclosure exhibits a high degree of conformality, such as greater than about 90% step coverage, enabling the Ge-containing material to be used to form high aspect ratio features or planar features of electronic devices. In addition, while the subvalent Ge precursors may include halogen atoms, the methods of the disclosure do not produce reactive halogen containing species (i.e., are free of the reactive halogen-containing species) and do not use a plasma (i.e., are plasma free).

The subvalent germanium precursor according to embodiments of the disclosure is sufficiently reactive with a reducing agent, such as an ammonia, to form monolayers of the Ge by the ALD process or the ALE process. Additionally, the subvalent germanium precursor is sufficiently stable to be used under vapor delivery conditions of the ALD process or the ALE process. The subvalent Ge precursor exhibits similar or better reactivity when compared to conventional Ge precursors such as GeBAMDN. By selecting substituents on the amidinate, along with the R⁴ substituent, the reactivity of the subvalent Ge precursor may be tailored (e.g., adjusted) to achieve a desired level of reactivity or thermodynamic favorability while maintaining thermodynamic stability in the subvalent Ge precursor. By way of example, the subvalent Ge precursor may be adjusted to selectively have thermodynamic favorability such that the temperature window of the ALD process may be controlled.

An atomic layer (e.g., monolayer) of Ge may be formed by reacting the subvalent germanium precursor and the reducing agent, such as ammonia (NH₃), on the material (e.g., the base material) of the electronic device in the deposition chamber. The deposition chamber may be a conventional reaction chamber or a conventional deposition chamber, such as a conventional ALD reactor or a conventional ALE reactor, which are not described in detail here. The reducing agent and the subvalent Ge precursor are reacted to form the Ge monolayer. The reaction conditions within the deposition chamber, such as temperature, pressure, and time may be adjusted to control the formation of the Ge monolayer. By varying the temperature and/or pressure, the formation rate of the Ge monolayer may be controlled. By way of example only, the Ge monolayer may be formed by the ALD process or the ALE process at a temperature of from about 20° C. to about 300° C., such as from about 20° C. to about 200° C. or from about 20° C. to about 150° C. The amount of reducing agent and subvalent Ge precursor may be varied to control the formation of the Ge monolayer. Increasing the amount of time (e.g., dosage time) that the substrate is exposed to the reducing agent and the subvalent Ge precursor enables the reducing agent and the subvalent Ge precursor to fully diffuse in the deposition chamber.

Additional monolayers of Ge may be formed over the monolayers of Ge to increase a thickness of the elemental germanium. Sequentially introducing the reducing agent and the subvalent Ge precursor in a cyclic manner forms additional monolayers of Ge, one monolayer formed over another, to form the elemental germanium at a desired thickness. By way of example only, each cycle may form about 0.3 angstroms (Å) of the monolayer of Ge. An overall thickness of the germanium-containing material Ge may be in the range of from about 10 Å to about 30 Å.

While the formation of elemental germanium is discussed above, the subvalent germanium precursor may be used to form other germanium-containing materials, such as SiGe, phosphorous doped Ge, or the chalcogenide material including germanium. Such a germanium-containing material may be formed by sequentially introducing the subvalent germanium precursor and a precursor of another element into the deposition chamber under conditions of the ALD process or the ALE process. By way of example only, if the germanium-containing material is SiGe, the SiGe may be formed by sequentially introducing the subvalent germanium precursor and a silicon precursor to form the SiGe. The process of sequentially introducing the subvalent germanium precursor and the silicon precursor may be repeated for a desired number of cycles until a desired thickness of the SiGe is obtained. The relative amounts of silicon and germanium in the SiGe may be tailored by controlling the number of cycles of introducing the subvalent germanium precursor and the silicon precursor. The silicon precursor may include, but is not limited to, silane. Similarly, if the germanium-containing material includes phosphorous doped Ge, phosphorus may be incorporated into the elemental germanium to achieve a desired concentration of the phosphorus in the germanium-containing material.

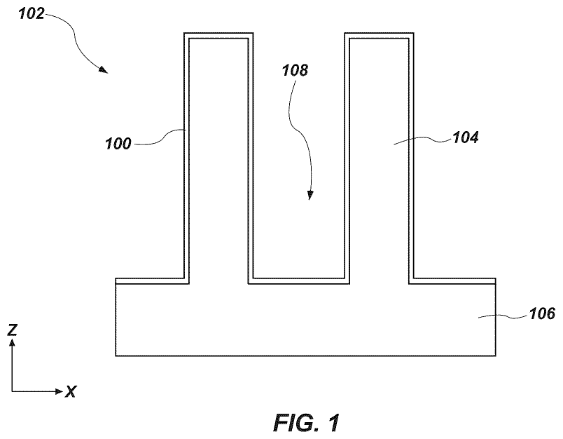

As shown in FIG. 1, a germanium-containing material 100 may be conformally formed on an electronic device 102 having at least one feature 104 with a high aspect ratio. The electronic device 102 may include a substrate 106 having openings 108 therein that define the features 104. The features 104 are formed from the material of the substrate 106. However, the substrate 106 may include one or more materials, layers, structures, or regions thereon, such as a stack structure, which make up the features 104. The materials of the stack structure may be formed by conventional techniques, which are not described in detail herein. The features 104 may have a high aspect ratio, such as an aspect ratio of at least about 10:1, such as at least about 15:1 at least about 50:1, at least about 75:1, or at least about 100:1. The germanium-containing material 100 may be formed over the features 104 according to embodiments of the disclosure. The germanium-containing material 100 may, alternatively, be formed on the electronic device 102 as a planar material (not shown).

The germanium-containing material 100 may be present in an electronic device, such as in a 3-dimensional (3D) electronic device. By way of example only, the electronic device may be a 3D NAND device, a 3D DRAM device, a 3D crosspoint device, or other memory device. The germanium-containing material 100 may be present in HAR features of the electronic device, such as HAR capacitor containers or HAR pillars (e.g., HAR memory pillars). The germanium-containing material 100 formed by the methods of the disclosure exhibits a high degree of conformality and thickness uniformity, such as greater than about 90% step coverage, greater than about 95% step coverage, or greater than about 99% step coverage. The presence of the germanium-containing material 100 in the electronic device may provide reduced breakdown voltage and decreased leakage current compared to a germanium material formed by a conventional process, such as by a CVD process. The improvements in electrical performance are achieved without negatively affecting resistivity and capacitance of the electronic device.

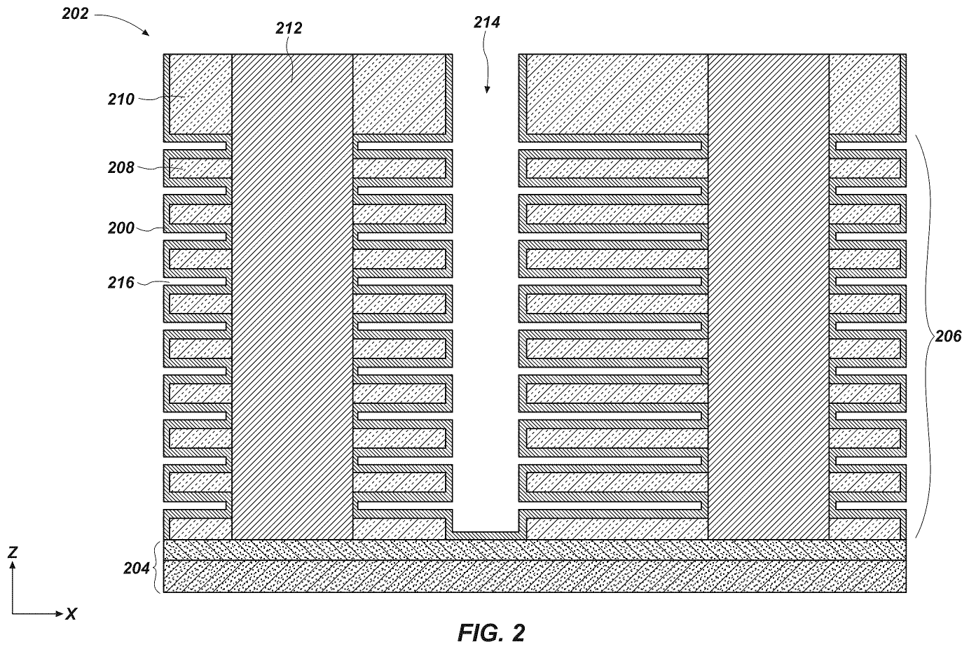

As shown in FIG. 2, germanium-containing material 200 may also be used in an electronic device 202 having, for example, at least one reentrant feature such as recesses 216. The electronic device 202 may, for example, be a portion of a memory device (e.g., a multi-deck 3D NAND Flash memory device, such as a dual-deck 3D NAND Flash memory device), as described in further detail below.

The electronic device 202 includes source 204 and a stack structure 206 vertically overlying (e.g., in the Z-direction) the source 204. The stack structure 206 may include a vertically alternating (e.g., in the Z-direction) sequence of insulative structures 208 and recesses 216. The stack structure 206 may include a dielectric material 210 vertically overlying the sequence of insulative structures 208 and recesses 216. The stack structure 206 may further include pillars 212 and openings 214 vertically extending through the stack structure 206. While the pillars 212 are illustrated as a single material for convenience, the pillars 212 may include cell films, a channel material, etc. Therefore, the electronic device 202 includes memory cells. The germanium-containing material 200 of the electronic device 202 may be used as a component (e.g., a transistor, a capacitor, a cell film) of an electronic device that occupies a reentrant feature. The germanium-containing material 200 may be conformally formed on the electronic device 202 having at least one feature that is reentrant. The materials of the stack structure 206 may be formed by conventional techniques, which are not described in detail herein.

The thickness of the germanium-containing material 200 may be controlled as previously discussed. By way of example, the germanium-containing material 200 is formed substantially continuously at a thickness in the range of from about 10 Å to about 30 Å adjacent to the reentrant feature of the electronic device 202.

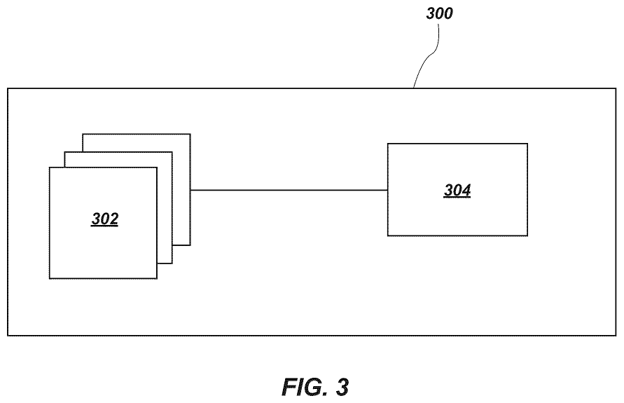

The electronic device 202 including the germanium-containing material 200 may be present in an electronic device 300, as shown in FIG. 3, which may be formed by conducting additional process acts depending on the electronic device 300 to be formed. The subsequent process acts are also conducted to electrically connect the germanium-containing material 200 to other components of the electronic device 300. The subsequent process acts are conducted by conventional techniques, which are not described in detail herein. By way of example only, the electronic device 300 may be a memory device that includes the reentrant features in a memory array of memory cells. The electronic device 300 includes a memory array 302 of memory cells including the germanium-containing material 100, 200 and a control logic component 304. The control logic component 304 may be configured to operatively interact with the memory array 302 so as to read, write, or re-fresh any or all memory cells within the memory array 302.

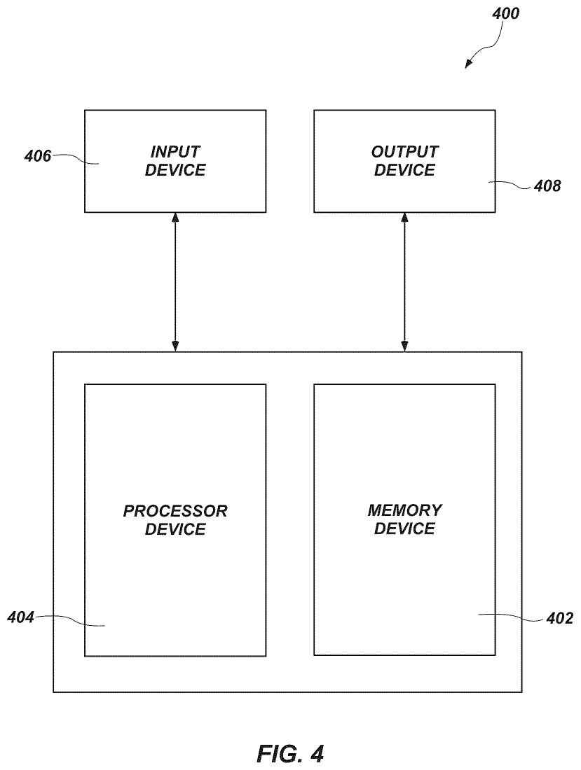

A system 400 is also disclosed, as shown in FIG. 4, and includes the germanium-containing material 100, 200. FIG. 4 is a simplified block diagram of the system 400 implemented according to one or more embodiments described herein. The system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The system 400 includes at least one memory device 402, which includes memory cells including the germanium-containing material 100, 200 as previously described. The system 400 may further include at least one processor device 404 (often referred to as a “processor”). The system 400 may further include one or more input devices 406 for inputting information into the system 400 by a user, such as, for example, a mouse or other pointing device, a keyboard, a touchpad, a button, or a control panel. The system 400 may further include one or more output devices 408 for outputting information (e.g., visual or audio output) to a user such as, for example, a monitor, a display, a printer, an audio output jack, a speaker, etc. In some embodiments, the input device 406 and the output device 408 may comprise a single touchscreen device that can be used both to input information to the system 400 and to output visual information to a user. The one or more input devices 406 and output devices 408 may communicate electrically with at least one of the memory device 402 and the processor device 404.

The following examples serve to explain embodiments of the disclosure in more detail. These examples are not to be construed as being exhaustive or exclusive as to the scope of this disclosure.

### EXAMPLES

### Example 1

### Synthesis of Germanium chloro

[2,2-dimethyl-N,N-bis(1-methylethyl)propanimidamidato]

As shown in the reaction scheme below, tBuLi is reacted with diisopropylcarbodiimide to form lithium [2,2,-dimethyl-N,N-bis(1-methylethyl)propanimidamidato].

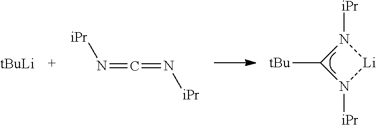

This is followed by a transmetalation reaction of a 1:1 stoichiometry of the lithium [2,2-dimethyl-N,N-bis(1-methylethyl)propanimidamidato] and Cl₂ Gedioxane, which are reacted with a slight excess of LiCl to transfer the amidinate ligand to the germanium, yielding the product germanium chloro [2,2-dimethyl-N,N-bis(1-methylethyl)propanimidamidato], as shown in the reaction scheme below.

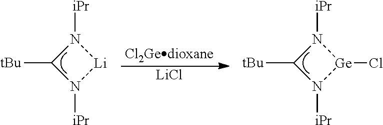

### Example 2

### Synthesis of Germanium chloro [N,N-bis(1methylethyl)pentanimidamidato]

As shown in the reaction scheme below, BuLi is reacted with diisopropylcarbodiimide to form lithium [N,N-bis(1-methylethyl)pentanimidamidato].

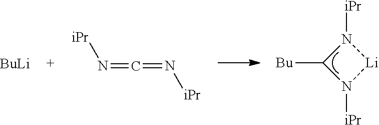

This is followed by a transmetalation reaction of a 1:1 stoichiometry of the lithium [N,N-bis(1-methylethyl)pentanimidamidato] and Cl₂Ge·dioxane, which are reacted with a slight excess of LiCl to transfer the amidinate ligand to the germanium yielding the product germanium chloro [N,N-bis(1-methylethyl)pentanimidamidato], as shown in the reaction scheme below.

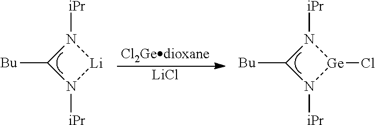

### Example 3

Synthesis of Germanium chloro [N,N-bis(1-methylethyl)benzylamidamidato]

As shown in the reaction scheme below, PhLi is reacted with diisopropylcarbodiimide to form lithium [N,N-bis(1-methylethyl)benzylanimidamidato].

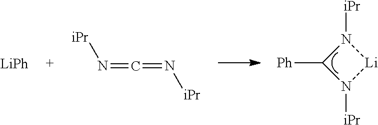

This is followed by a transmetalation reaction of a 1:1 stoichiometry of the lithium [N,N-bis(1-methylethyl)benzylanimidamidato] and Cl₂ Ge dioxane, which are reacted with a slight excess of LiCl to transfer the amidinate ligand to the germanium yielding the product germanium chloro [N,N-bis(1-methylethyl)benzylanimidamidato] as shown in the reaction scheme below.

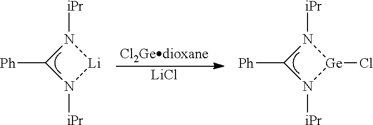

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A germanium precursor comprising:
a chemical structure of 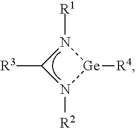
wherein each of R¹, R², R³, and R⁴ is independently selected from the group consisting of hydrogen, an alkyl, a substituted alkyl, an alkoxide, a substituted amide, an amine, a substituted amine, and a halogen.

2. The germanium precursor of claim 1, wherein R¹ and R² are the same.

3. The germanium precursor of claim 1, wherein R¹ comprises an isopropyl.

4. The germanium precursor of claim 1, wherein R⁴ comprises a halogen.

5. The germanium precursor of claim 1, wherein R³ comprises a butyl, a tertbutyl, or a phenyl.

6. The germanium precursor of claim 1, wherein the germanium precursor comprises

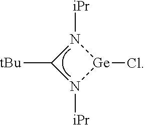

7. The germanium precursor of claim 1, wherein the germanium precursor comprises

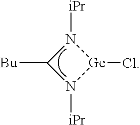

8. The germanium precursor of claim 1, wherein the germanium precursor comprises

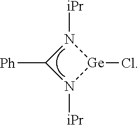

9. A method of forming a germanium precursor, comprising:
reacting an organolithium reagent with a carbodiimide to produce a lithium amidinate compound, the lithium amidinate compound comprising a chemical structure of 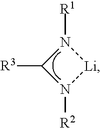
wherein each of R¹, R², and R³ is independently selected from the group consisting of hydrogen, an alkyl, a substituted alkyl, an alkoxide, a substituted amide, an amine, a substituted amine, and a halogen; and
reacting the lithium amidinate compound with a germanium source compound to form a germanium amidinate precursor comprising a chemical structure of 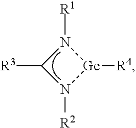
wherein R⁴ is selected from the group consisting of hydrogen, an alkyl, a substituted alkyl, an alkoxide, a substituted amide, an amine, a substituted amine, and a halogen.

10. The method of claim 9, wherein reacting the organolithium reagent with the carbodiimide comprises reacting butyllithium, tertbutyllithium, or phenyllithium with the carbodiimide.

11. The method of claim 9, wherein reacting the organolithium reagent with the carbodiimide comprises reacting the organolithium reagent with diisopropylcarbodiimide.

12. The method of claim 9, wherein reacting the lithium amidinate compound with the germanium source compound comprises reacting the lithium amidinate compound with germanium dichloride dioxane, germanium dibromide dioxane, or germanium diiodide dioxane.

13. A precursor composition comprising a germanium precursor and a solvent, the germanium precursor comprising:
a chemical structure of 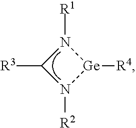
wherein each of R¹, R², R³, and R⁴ is independently selected from the group consisting of hydrogen, an alkyl, a substituted alkyl, an alkoxide, a substituted amide, an amine, a substituted amine, and a halogen.

14. The precursor composition of claim 13, wherein the germanium precursor comprises

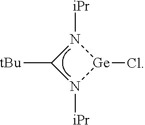

15. The precursor composition of claim 13, wherein the germanium precursor comprises

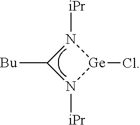

16. The precursor composition of claim 13, wherein the germanium precursor comprises [chemical structure]
